(19) United States
(12) Patent Application Publication
(10) Pub. No.: US 2011/0143034 A1
(43) Pub. Date: Jun. 16, 2011

(54) METHOD FOR DEPOSITING GRAPHENE FILM

(75) Inventors: Seongdeok Ahn, Daejeon (KR); Seung Youl Kang, Daejeon (KR)

(73) Assignee: Electronics and Telecommunications Research Institute, Daejeon (KR)

(21) Appl. No.: 12/829,381

(22) Filed: Jul. 1, 2010

(30) Foreign Application Priority Data
Dec. 11, 2009 (KR) 10-2009-0123339

(51) Int. Cl. C23C 16/26

(52) U.S. Cl. 427/249.6

(57) ABSTRACT

Provided is a method of depositing a graphene film. In the method includes supplying a gaseous-phase graphene source to a substrate, forming an adsorbed layer on the substrate by the graphene source, and activating the adsorbed layer by heating the adsorbed layer. Therefore, a uniform graphene film having a large area can be formed.

### CROSS-REFERENCE TO RELATED APPLICATIONS

This U.S. non-provisional patent application claims priority under 35 U.S.C. §119 of Korean Patent Application No. 10-2009-0123339, filed on Dec. 11, 2009, the entire contents of which are hereby incorporated by reference.

### BACKGROUND

The present invention disclosed herein relates to an apparatus and method for depositing a film, and more particularly, to an apparatus and method for depositing a graphene film.

Graphene is a substance composed of carbon atoms connected in a planar honeycomb shape. Graphene has only one atomic layer thickness but is stable structurally and chemically, and owing to its quantum mechanical characteristics, the electrical properties of graphene are also good. Electrons can move in graphene hundred or more times faster than in single crystal silicon, and hundred or more times larger current can flow through graphene than through copper. Due to these characteristics, graphene is considered to be the next generation of a material for transistors and electrodes.

However, it is difficult to extract micrometer or larger graphene from graphite. In other words, since it is difficult to make graphene having a large area, application of graphene to, for example, semiconductor fields is not easy.

### SUMMARY

The present invention provides a method of depositing a graphene film having a large area.

The present invention also provides a method of depositing a uniform graphene film having a large area by using a time division rapid heating method.

Some embodiments of the present invention may provide methods for depositing a graphene film, the methods including: supplying a gaseous-phase graphene source to a substrate; adsorbing the graphene source to form an adsorbed layer on the substrate; and activating the adsorbed layer by heating the adsorbed layer.

In some embodiments, the supplying of the graphene source may include supplying a carbon compound.

In other embodiments, the supplying of the carbon compound includes supplying a gaseous-phase material selected from the group consisting of carbon monoxide, methane, ethane, ethylene, ethanol, acetylene, propane, propylene, butane, butadiene, pentane, pentene, cyclopentadiene, hexane, cyclohexane, benzene, toluene, and combinations thereof.

In still other embodiments, the forming of the adsorbed layer may include cooling the substrate to room temperature or lower so as to allow the substrate to adsorb the gaseous-phase graphene source.

In even other embodiments, the activating of the adsorbed layer may include heating the adsorbed layer to room temperature or higher so as to allow carbon components of the adsorbed layer to couple with each other.

In yet other embodiments, the activating of the adsorbed layer may further include supplying a gaseous-phase activation source to the adsorbed layer.

In further embodiments, the supplying of the gaseous-phase activation source may include supplying a gaseous-phase material including at least one selected from the group consisting of N, NH₃, Ni, Co, Fe, Pt, Au, Al, Cr, Cu, Mg, Mn, Mo, Rh, Si, Ta, Ti, W, U, V, and Zr.

In still further embodiments, the supplying of the graphene source may further include supplying a dilute gas to the substrate.

In even further embodiments, the supplying of the dilute gas may include supplying one selected from the group consisting of noble gas, nitrogen, ammonia, hydrogen, and combinations thereof together with the graphene source.

Other embodiments of the present invention may provide methods of depositing a graphene film, the methods including: providing a graphene film depositing apparatus including a process chamber in which a substrate cooling unit and a rapid heating unit are disposed; providing a substrate into the process to support the substrate on the substrate cooling unit; supplying a gaseous-phase graphene source to the process chamber to form an adsorbed layer on the substrate; purging the graphene source remaining in the process chamber after the adsorbed layer is formed; supplying a gaseous-phase activation source to the process chamber; activating the adsorbed layer by heating the substrate using the rapid heating unit; and purging the activation source remaining in the process chamber after the adsorbed layer is activated.

In some embodiments, prior to the supplying of the graphene source to the process chamber, the method may further include bypassing the graphene source and the activation source through a passage so as to keep flows of the graphene source and the activation source in steady state inside the graphene film depositing apparatus.

In other embodiments, the supplying of the graphene source to the process chamber may include supplying a dilute gas to the process chamber together with the graphene source so as to keep the process chamber at a pressure equal to or lower than atmospheric pressure.

In still other embodiments, the supplying of the graphene source to the process chamber may include bypassing the activation source through a passage so as to keep a flow of the activation source in steady state inside the graphene film depositing apparatus.

In even other embodiments, the supplying of the activation source to the process chamber may include bypassing the graphene source through a passage so as to keep a flow of the graphene source in steady state inside the graphene film depositing apparatus.

In yet other embodiments, the graphene source and the activation source may be alternately supplied to the process chamber for a time divided into 0.01-second to several-hour time periods.

In further embodiments, the graphene film depositing apparatus may further include a heating block configured to heat at least one of the graphene source and the activation source so as to evaporate the least one source or prevent condensation of the at least one source.

In still further embodiments, the heating block may be configured to heat the graphene source and the activation source individually or interactively.

In even further embodiments, after the activating of the adsorbed layer, the method may further include cooling the substrate to a temperature where at least carbon decomposition does not occur.

In yet further embodiments, the cooling of the substrate may include cooling the substrate to about 500 Celsius or room temperature where carbon decomposition does not occur.

In some embodiments, the activating of the adsorbed layer by heating the substrate may include heating the substrate to a temperature ranging from about 700 Celsius to about 1100 Celsius.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a view illustrating a graphene film depositing apparatus according to an embodiment of the present invention; and

FIG. 2 is a flowchart for explaining a graphene film depositing method according to an embodiment of the present invention.

### DETAILED DESCRIPTION OF EMBODIMENTS

A method for depositing a graphene film will be now be described with reference to the accompanying drawings according to exemplary embodiments of the present invention.

Advantages of the present invention in comparison with the related art will be clarified through the Detailed Description of Preferred Embodiments and the Claims with reference to the accompanying drawings. In particular, the present invention is well pointed out and clearly claimed in the Claims. The present invention, however, may be best appreciated by referring to the following Detailed Description of Preferred Embodiments with reference to the accompanying drawings. In the drawings, like reference numerals refer to like elements throughout

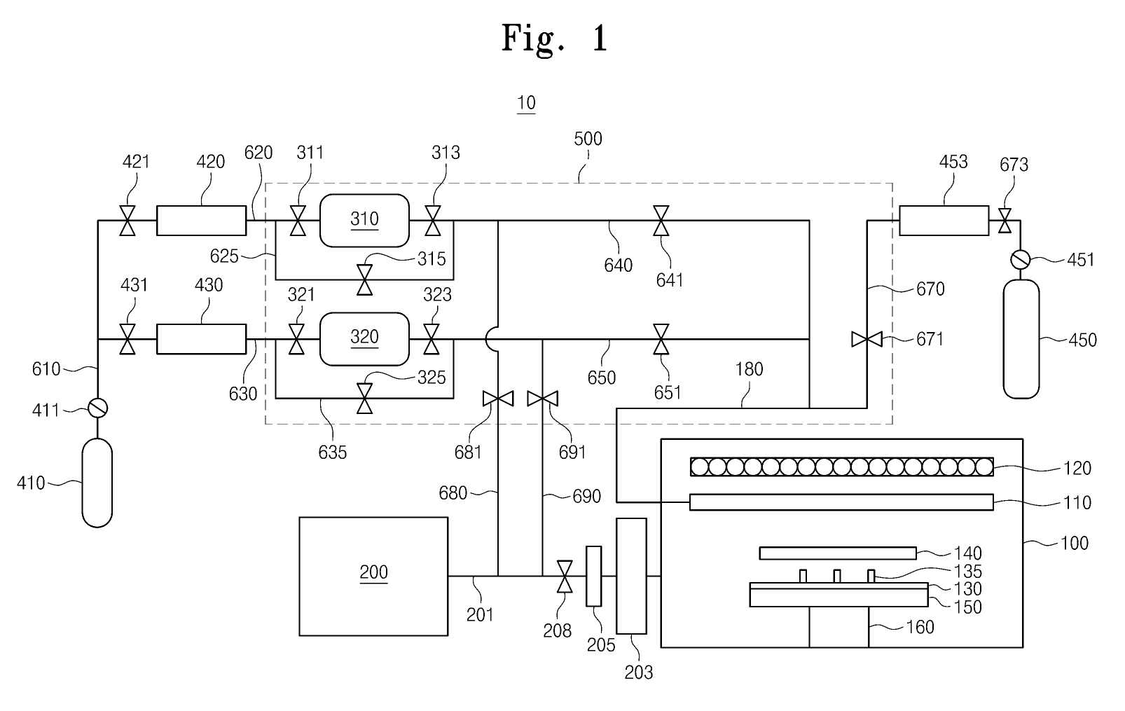

FIG. 1 is a view illustrating a graphene film depositing apparatus 10 according to an embodiment of the present invention. In this specification, the term “front side” is used to denote a side of a device through which a material is introduced into the device, and the opposite side is denoted by the term “rear side.”

Referring to FIG. 1, the graphene film depositing apparatus 10 may include: a process chamber 100 in which a graphene film depositing process is performed; a deposition source tank 310 in which a graphene source is stored for supplying it to the process chamber 100; an activation source tank 320 in which an activation source for activating the graphene source is stored; a carrier gas tank 410 in which a carrier gas is stored for carrying the graphene source to the process chamber 100; a dilute gas tank 450 in which a dilute gas is stored for adjusting the pressure of the process chamber 100; a vacuum pump 200 configured to create a vacuum in the process chamber 100; and a heating block 500 configured to evaporate the graphene source stored in the deposition source tank 310.

The process chamber 100 may be configured to deposit a graphene film on a substrate 140. For example, a substrate support 130 and a substrate cooling unit 150 may be disposed in a lower inner side of the process chamber 100, and a shower ring 110 and a rapid heating unit may be disposed in an upper inner side of the process chamber 100.

The substrate 140 may be disposed on the substrate support 130. The substrate 140 may be placed on or off the substrate support 130 in a state where the substrate 140 is supported on a plurality of movable lift pins 135. The substrate support 130 may be configured to be rotated or lifted/lowered in a state where the substrate support 130 is connected to a support shaft 160. The substrate cooling unit 150 may be disposed under the substrate support 130. The substrate cooling unit 150 may be used to cool the substrate 140 placed on the substrate support 130 so that a graphene source can be uniformly adsorbed in the substrate 140. The substrate cooling unit 150 may include a cooling line in which refrigerant flows.

A graphene source carried from the deposition source tank 310 may be uniformly distributed on the substrate 140 through the shower ring 110. The graphene source may be provided through a main line 180 in gaseous phase. The shower ring 110 may have a double ring structure. The rapid heating unit 120 may include a heating device such as a heating coil, a halogen lamp or an infrared lamp. The rapid heating unit 120 may apply heat or infrared rays to the substrate 140 to increase the temperature of the substrate 140. As the temperature of the substrate 140 increases, a graphene source adsorbed in the substrate 140 may be activated. The rapid heating unit 120 may be disposed at the upper side of the shower ring 110 not to hinder supply of a graphene source to the substrate 140. Condensation of a graphene source at the shower ring 110 can be prevented by heating the shower ring 110 with the rapid heating unit 120. Alternatively, a shower ring heating unit may further be provided so as to heat the shower ring 110 selectively.

The vacuum pump 200 may be connected to a side of the process chamber 100 for creating a vacuum in the process chamber 100. The vacuum pump 200 may include a rotary pump capable of evacuating the process chamber 100 to about 0.001 Torr to 100 Torr. The vacuum pump 200 may further include a turbo pump for further evacuating the process chamber 100.

An exhaust line 201 may be connected between the process chamber 100 and the vacuum pump 200. A trap 203 may be coupled to the exhaust line 201 so as to remove byproducts of a graphene film depositing process such as vapor having influence on the performance of the vacuum pump 200. The trap 203 may include a cold trap. Since the trap 203 condenses byproducts, the vacuum pump 200 can be protected from byproducts. The trap 203 may be filled with a material such as liquid nitrogen, natural oil, or fluorocarbon oil so as to condense byproducts. A throttle valve 205 may be provided at the exhaust line 201 between the vacuum pump 200 and the trap 203 so as to regulate the pressure of the process chamber 100.

The deposition source tank 310 may store a graphene source to be supplied to the process chamber 100. The graphene source may be supplied to the main line 180 through a deposition source line 640 disposed between the deposition source tank 310 and the process chamber 100, and then the graphene source may be introduced into the shower ring 110 from the main line 180. A source chamber in quick switching valve 641 (hereinafter, also referred to as a first valve) may be disposed at the deposition source line 640 to control supply of a graphene source to the process chamber 100. The first valve 641 may include a valve openable/closable according to time divisions, such as a quick switching valve openable/closable with about 0.01 to 0.05 second operation precision. All valves of the present invention may include such a quick switching valve. A plurality of deposition source tanks 310 may be provided, In this case, the plurality of deposition source tanks 310 may be connected in parallel.

An activation source or a thermal initiator may be supplied to the process chamber 100 for activating a graphene source. For this, the activation source tank 320 may be provided. The activation source may be supplied to the main line 180 through an activation source line 650 disposed between the activation source tank 320 and the process chamber 100, and then the activation source may be introduced into the shower ring 110 from the main line 180. The activation source may be supplied to the shower ring 110 in gaseous phase. A source chamber in quick switching valve 651 (hereinafter, also referred to as a second) may be disposed at the activation source line 650 to control supply of an activation source to the process chamber 100. If a plurality of activation source tanks 320 are used, the activation source tanks 320 may be connected in parallel. The deposition source tank 310 and the activation source tank 320 may be connected in parallel.

A source in quick switching valve 313 (hereinafter, also referred to as a third valve) may be disposed at the rear side of the deposition source tank 310 so as to control a flow of a graphene source from the deposition source tank 310 to the deposition source line 640. Similarly, a source in quick switching valve 323 (hereinafter, also referred to as a fourth valve) may be disposed at the rear side of the activation source tank 320 so as to control a flow of an activation source from the activation source tank 320 to the activation source line 650.

The graphene source may be carried from the deposition source tank 310 to the process chamber 100 by a flow of a carrier gas. A carrier gas may be stored in the carrier gas tank 410. Carrier gas lines 610 and 620 may be disposed between the carrier gas tank 410 and the deposition source tank 310 to provide carrier gas flow passages. The carrier gas lines 610 and 620 may be distinguished as a main carrier gas line 610 and a first carrier gas line 620. The activation source may be carried from the activation source tank 320 to the process chamber 100 by a flow of a carrier gas. A second carrier gas line 630 branching off from the main carrier gas line 610 may be disposed between the carrier gas tank 410 and the activation source tank 320.

Devices may be used for precisely controlling flows of a carrier gas from the carrier gas tank 410 to the deposition and activation source tanks 310 and 320. For example, a first regulating valve 411 may be disposed at the main carrier gas line 610, and first and second flow meters 420 and 430 may be disposed at the first and second carrier gas lines 620 and 630, respectively. One or more valves may be further provided to control flows of the carrier gas. For example, a quick switching valve 421 (hereinafter, also referred to as a fifth valve) may be disposed at the first carrier gas line 620, and a quick switching valve 431 (hereinafter, also referred to as a sixth valve) may be disposed at the second carrier gas line 630. The fifth valve 421 may be disposed at the front side of the first flow meter 420, and the sixth valve 431 may be disposed at the front side of the second flow meter 430.

The graphene film depositing apparatus 10 may be configured to perform a purge process. For example, the graphene film depositing apparatus 10 may include a first purge gas line 625 bypassing the deposition source tank 310, and a second purge gas line 635 bypassing the activation source tank 320. A source purge quick switching valve 315 (hereinafter, also referred to as a first purge valve) may be disposed at the first purge gas line 625 so as to control a flow of a purge gas. Similarly, a source purge quick switching valve 325 (hereinafter, also referred to as a second purge valve) may be disposed at the second purge gas line 635 so as to control a flow of the purge gas. The carrier gas stored in the carrier gas tank 410 may be used as the purge gas.

The graphene film depositing apparatus 10 may be configured to bypass the graphene source and/or the activation source. For example, a first bypass line 680 may be coupled to the deposition source line 640 so as to bypass the graphene source from the deposition source tank 310 to the exhaust line 201 so that the graphene source may not flow to the process chamber 100. A source bypass quick switching valve 681 (hereinafter, also referred to as a first bypass valve) may be disposed at the first bypass line 680 so as to control a flow of the graphene source. Similarly, a second bypass line 690 may be coupled to the activation source line 650 so as to bypass the activation source from the activation source tank 320 to the exhaust line 201 so that the activation source may not flow to the process chamber 100. A source bypass quick switching valve 691 (hereinafter, also referred to as a second bypass valve) may be disposed at the second bypass line 690 so as to control a flow of the activation source.

A source out quick switching valve 311 (hereinafter, also referred to as a seventh valve) may be provided so as to control a bypass flow of the graphene source from the deposition source tank 310 to the first bypass line 680. The seventh valve 311 may be disposed at the first carrier gas line 620 connected to the front side of the deposition source tank 310. Similarly, a source out quick switching valve 321 (hereinafter, also referred to as an eighth valve) may be provided so as to control a bypass flow of the activation source from the activation source tank 320 to the second bypass line 690. The eighth valve 321 may be disposed at the second carrier gas line 630 connected to the front side of the activation source tank 320.

A process chamber quick switching valve 208 (hereinafter, also referred to as a ninth valve) may be disposed at the discharge line 201 so as to prevent bypass flows of the graphene source and/or the activation source from flowing into the process chamber 100. The ninth valve 208 may be disposed at the rear side of the throttle valve 205. The ninth valve 208 may be opened when the process chamber 100 is evacuated.

The graphene film depositing apparatus 10 may be configured so that the pressure of the process chamber 100 can be adjusted during the graphene film depositing process. For example, the dilute gas stored in the dilute gas tank 450 may be supplied to the process chamber 100 when the graphene source is supplied to the process chamber 100 so as to adjust the pressure of the process chamber 100. A dilute gas line 670 may be disposed between the dilute gas tank 450 and the process chamber 100 so as to provide a dilute gas flow passage. A source chamber gas in quick switching valve 671 (hereinafter, also referred to as a tenth valve) may be disposed at the dilute gas line 670 so as to control a flow of the dilute gas. A regulating valve 451 and a flow meter 453 may be disposed along the dilute gas line 670 at the rear side of the dilute gas tank 450 for precisely controlling supply of the dilute gas. In addition, a quick switching valve 673 (hereinafter, also referred to as a eleventh valve) may be disposed at the dilute gas line 670 between the flow meter 453 and the regulating valve 451 so as to control a flow of the dilute gas.

The graphene film depositing apparatus 10 may be configured to evaporate sources used in the film depositing process or prevent condensation of evaporated sources. For example, the graphene film depositing apparatus 10 may include the heating block 500. The heating block 500 may have a shape surrounding regions where sources are located. For example, the heating block 500 may have a shape surrounding the deposition source tank 310, the activation source tank 320, and various lines and valves disposed around the tanks 310 and 320. Alternatively, the heating block 500 may be divided into parts for individually or interactively heating the deposition source tank 310, the activation source tank 320, and various lines and valves disposed around the tanks 310 and 320.

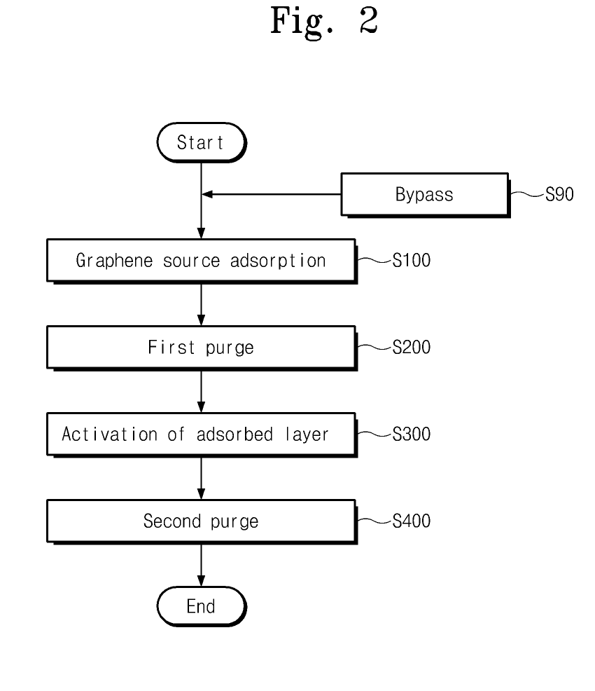

FIG. 2 is a flowchart for explaining a graphene film depositing method according to an embodiment of the present invention. In the present embodiment, graphene film deposition processes may be carried out by using the graphene film depositing apparatus 10 illustrated in FIG. 1.

Referring to FIGS. 1 and 2, an operation S100 of adsorbing the graphene source, an operation S200 of purging a remaining graphene source, an operation S300 of activating an adsorbed layer using the activation source, and an operation S400 of purging a remaining activation source may be repeated for one or more cycles, so as to form a graphene film.

In a first operation S100, the graphene source may be supplied to the process chamber 100 so that the substrate 140 can adsorb the graphene source. For example, the first valve 641 and the third valve 313 may be opened to supply the graphene source from the deposition source tank 310 to the process chamber 100. At this time, the fifth valve 421 and the seventh valve 311 may be also opened to create a flow of the carrier gas for carrying the graphene source by using the flow of the carrier gas, but the second valve 651 may be kept in a closed state. The graphene source supplied to the process chamber 100 may uniformly be distributed to the substrate 140 through the shower ring 110 so that the substrate 140 can adsorb the graphene source. The graphene source may be adsorbed in the form of a monomer. The substrate 140 may be cooled by the substrate cooling unit 150 to facilitate adsorption of the graphene source. In the first operation S100, the tenth valve 671 may be opened to supply the dilute gas to the process chamber 100 for adjusting the pressure of the process chamber 100. The process chamber 100 may be kept at a pressure lower than atmospheric pressure, for example, about 0.001 Torr to about 100 Torr. The dilute gas may be supplied to the process chamber 100 together with the graphene source.

The graphene source may be supplied to the process chamber 100 in a gaseous phase. The graphene source may be any material capable of providing carbon. Examples of a material that can be used as the graphene source include a carbon compound such as carbon monoxide, methane, ethane, ethylene, ethanol, acetylene, propane, propylene, butane, butadiene, pentane, pentene, cyclopentadiene, hexane, cyclohexane, benzene, and toluene. The graphene source may be gas or liquid.

The graphene source may be stored in the deposition source tank 310 in liquid phase and supplied to the process chamber 100 after being evaporated into gaseous phase. Alternatively, the graphene source may be stored in the deposition source tank 310 in gaseous phase. A single material may be used as the graphene source, and a plurality of materials may be used as the graphene source. In the latter case, a plurality of deposition source tanks 310 as many as the number of graphene sources may be provided.

Examples of the substrate 140 may include a metal substrate, a semiconductor substrate, an insulator substrate, and a plastic substrate. The substrate 140 may have any shape such as circular, square, and rectangular shapes.

Examples of the carrier gas may include noble gases such as helium gas, argon gas, krypton gas, and neon gas, and nitrogen gas. Like the carrier gas, examples of the dilute gas may include nitrogen gas and noble gas. Alternatively, the dilute gas may be a reactive gas such as ammonia gas and hydrogen gas. In the case where ammonia gas is used as the dilute gas, the ammonia gas may also function as a nitrogen doping gas.

Before the first operation S100, the graphene source and the activation source may be bypassed (S90). For example, the seventh valve 311, the first purge valve 315, and the first bypass valve 681 may be opened to bypass the graphene source. At this time, the fifth valve 421 may be opened to create a flow of the carrier gas so as to bypass the graphene source using the flow of the carrier gas. Along with this, the eighth valve 321, the second purge valve 325, and the second bypass valve 691 may be opened to bypass the activation source. By the bypassing operation S90, flows of the graphene source and the activation source can be kept in steady state. At this time, the sixth valve 431 may be opened to create a flow of the carrier gas so as to bypass the activation source by the flow of the carrier gas.

In a second operation S200, the process chamber 100 may be purged. For example, the first purge valve 315 and the first valve 641 may be opened to supply the carrier gas to the process chamber 100 for removing the graphene source and byproducts remaining in the process chamber 100. The remaining graphene source and byproducts may be discharged from the process chamber 100 using the vacuum pump 200. During the purging operation S200, the eighth valve 321, the second purge gas 325, and the second bypass valve 691 may be opened so as to bypass the activation source. By this bypassing operation, the activation source can flow in steady state.

In a third operation S300, the activation source may be supplied to the process chamber 100 so as to activate a graphene source adsorbed layer. For example, the second valve 651, the fourth valve 323, and the eighth valve 321 may be opened so as to supply the activation source from the activation source tank 320 to the process chamber 100. At this time, the sixth valve 431 and the eighth valve 321 may be opened so as to create a flow of the carrier gas for carrying the activation source using the flow of the carrier gas, but the first valve 641 may be kept in a closed state. Along with this, the rapid heating unit 120 may be operated to heat the substrate 140. The rapid heating unit 120 may heat the substrate 140 to a temperature where the graphene source can be activated. By this heating, the graphene source adsorbed layer formed on the substrate 140 can be activated.

The substrate 140 may be heated to a temperature higher than room temperature, for example, about 700 Celsius to about 1100 Celsius. If the graphene source is in gaseous phase, the substrate 140 may be heated to a temperature ranging from about 900 Celsius to about 1100 Celsius. On the other hand, if the graphene source is in liquid phase, the substrate 140 may be less heated to about 900 Celsius or lower, for example, about 700 Celsius to about 900 Celsius. In the current embodiment of the present invention, the substrate 140 may be heated from room temperature to about 1000 Celsius within about 10 seconds.

The activation source may include a material capable of activating the adsorbed graphene source. For example, a material including at least one selected from the group consisting of N, NH₃, Ni, Co, Fe, Pt, Au, Al, Cr, Cu, Mg, Mn, Mo, Rh, Si, Ta, Ti, W, U, V, and Zr may be used as the activation source. Alternatively, the activation source may include ammonia or hydrogen. In the case where a plurality of kinds of liquid-phase materials are used as the graphene source, a plurality of liquid-phase materials, for example, three or four liquid-phase materials may be deposited to form a graphene film. In this case, different activation sources may be used for the liquid-phase materials, respectively. A plurality of activation source tanks 320 as many as the number of activation sources may be provided. After being activated by the activation source, the adsorbed layer may have a planar hexagonal shape formed by coupled carbon components. In the case where the graphene source is a liquid-phase source having a polymer structure, the graphene source may become dimer or polymer instead of monomer when being evaporated. In the case, the graphene source may be cracked into monomer by the activation source and then deposited.

The substrate 140 where the graphene film is deposited can be cooled using the substrate cooling unit 150. For example, the temperature of the substrate 140 can be decreased to room temperature. It may take time to decrease the temperature of the substrate 140 to room temperature. Thus, alternatively, the temperature of the substrate 140 may be decreased to a temperature where carbon decomposition does not occur, for example, about 500 Celsius, so as to reduce the processing time.

In a fourth operation S400, the process chamber 100 may be purged. For example, the second purge gas 325 and the second valve 651 may be opened to supply the carrier gas to the process chamber 100 for purging the activation source and byproducts remaining in the process chamber 100. This purging operation of the remaining activation source and byproducts from the process chamber 100 may be performed using the vacuum pump 200. During the purging operation, the seventh valve 311, the first purge valve 315, and the first bypass valve 681 may be opened to bypass the graphene source. By the bypassing operation, the flow of the graphene source can be kept in steady state.

A graphene film may be formed by repeating the first to fourth operations S100 to S400 one or more cycles. Each of the first to fourth operations S100 to S400 may be repeated one or more times. The first to fourth operations S100 to S400 may be alternately repeated, each for a divided time of about 0.01 seconds to several hours. During cycles, the graphene source and/or activation source may be kept at room temperature or higher, for example, about 300 Celsius or higher, so as to prevent condensation.

The exemplary embodiment of the present invention makes it possible to form a uniform single-layer graphene film having an area equal to or larger than the size of a wafer used in a semiconductor manufacturing process, such as 5 inch to 12 inch wafers. In addition, a single-layer graphene film having a thickness of, for example, about 1 nm, can be formed. Furthermore, a graphene film having a thickness equal to or greater than 1 nm can be formed by repeating cycles. In the case where a graphene film having a size equal to a 5-inch wafer, the graphene film can be uniformly formed with a thickness deviation of several percents.

A graphene source adsorbed layer can be activated without an activation source by applying sufficient heat to the graphene source adsorbed layer. Therefore, in the third operation S300, without using an activation source, the adsorbed layer can be activated to form a graphene film by heating the adsorbed layer with the rapid heating unit 120.

According to the present invention, a single-layer graphene film having a large area can be formed by using a time division rapid heating method. In addition, a graphene film having a size equal to or greater than sizes of currently-used wafers can be formed for application in semiconductor fields, and thus semiconductor devices and electronic/electric devices having good electric characteristics, and structural and chemical stability can be manufactured.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method for depositing a graphene film, the method comprising:
supplying a gaseous-phase graphene source to a substrate;
adsorbing the grapheme source to form an adsorbed layer on the substrate; and
activating the adsorbed layer by heating the adsorbed layer.

2. The method of claim 1, wherein the supplying of the graphene source comprises supplying a carbon compound.

3. The method of claim 2, wherein the supplying of the carbon compound comprises supplying a gaseous-phase material selected from the group consisting of carbon monoxide, methane, ethane, ethylene, ethanol, acetylene, propane, propylene, butane, butadiene, pentane, pentene, cyclopentadiene, hexane, cyclohexane, benzene, toluene, and combinations thereof.

4. The method of claim 1, wherein the forming of the adsorbed layer comprises cooling the substrate to room temperature or lower so as to allow the substrate to adsorb the gaseous-phase graphene source.

5. The method of claim 1, wherein the activating of the adsorbed layer comprises heating the adsorbed layer to room temperature or higher so as to allow carbon components of the adsorbed layer to couple with each other.

6. The method of claim 1, wherein the activating of the adsorbed layer further comprises supplying a gaseous-phase activation source to the adsorbed layer.

7. The method of claim 6, wherein the supplying of the gaseous-phase activation source comprises supplying a gaseous-phase material comprising at least one selected from the group consisting of N, NH₃, Ni, Co, Fe, Pt, Au, Al, Cr, Cu, Mg, Mn, Mo, Rh, Si, Ta, Ti, W, U, V, and Zr.

8. The method of claim 9, wherein the supplying of the graphene source further comprises supplying a dilute gas to the substrate.

9. The method of claim 8, wherein the supplying of the dilute gas comprises supplying one selected from the group consisting of noble gas, nitrogen, ammonia, hydrogen, and combinations thereof together with the graphene source.

10. A method of depositing a graphene film, the method comprising:
providing a graphene film depositing apparatus comprising a process chamber in which a substrate cooling unit and a rapid heating unit are disposed;
providing a substrate into the process to support the substrate on the substrate cooling unit;
supplying a gaseous-phase graphene source to the process chamber to form an adsorbed layer on the substrate;
purging the graphene source remaining in the process chamber after the adsorbed layer is formed;
supplying a gaseous-phase activation source to the process chamber;
activating the adsorbed layer by heating the substrate using the rapid heating unit; and
purging the activation source remaining in the process chamber after the adsorbed layer is activated.

11. The method of claim 10, wherein prior to the supplying of the graphene source to the process chamber, the method further comprises bypassing the graphene source and the activation source through a passage so as to keep flows of the graphene source and the activation source in steady state inside the graphene film depositing apparatus.

12. The method of claim 10, wherein the supplying of the graphene source to the process chamber comprises supplying a dilute gas to the process chamber together with the graphene source so as to keep the process chamber at a pressure equal to or lower than atmospheric pressure.

13. The method of claim 10, wherein the supplying of the graphene source to the process chamber comprises bypassing the activation source through a passage so as to keep a flow of the activation source in steady state inside the graphene film depositing apparatus.

14. The method of claim 10, wherein the supplying of the activation source to the process chamber comprises bypassing the graphene source through a passage so as to keep a flow of the graphene source in steady state inside the graphene film depositing apparatus.

15. The method of claim 10, wherein the graphene source and the activation source are alternately supplied to the process chamber for a time divided into 0.01-second to several-hour time periods.

16. The method of claim 10, wherein the graphene film depositing apparatus further comprises a heating block configured to heat at least one of the graphene source and the activation source so as to evaporate the at least one source or prevent condensation of the least one source.

17. The method of claim 16, wherein the heating block is configured to heat the graphene source and the activation source individually or interactively.

18. The method of claim 10, wherein after the activating of the adsorbed layer, the method further comprises cooling the substrate to a temperature where at least carbon decomposition does not occur.

19. The method of claim 18, wherein the cooling of the substrate comprise cooling the substrate to about 500 Celsius or room temperature where carbon decomposition does not occur.

20. The method of claim 10, wherein the activating of the adsorbed layer by heating the substrate comprises heating the substrate to a temperature ranging from about 700 Celsius to about 1100 Celsius.
